(19) United States
(12) Patent Application Publication
(10) Pub. No.: US 2002/0154487 A1
(43) Pub. Date: Oct. 24, 2002

(54) Radio frequency module of an audio appliance having optimum heat dissipation

(76) Inventor: Reinhard Weischhoff Van Rijn, Rambouillet (FR)

Correspondence Address: Kevin R. Spivak, Morrison & Foerster LLP, Suite 5500, 2000 Pennsylvania Avenue, N.W., Washington, DC, 20006-1888, US

(21) Appl. No.: 10/115,285

(22) Filed: Apr. 4, 2002

(30) Foreign Application Priority Data
Apr. 4, 2001 (EP) 01107769.0

(51) Int. Cl. H05K 7/20

(52) U.S. Cl. 361/719

(57) ABSTRACT

A radio frequency module of an audio appliance, in particular of a car radio, has at least one electrical component which produces heat loss and has optimum heat dissipation. The electrical component producing heat loss is mounted on a printed circuit board arranged inside a metal housing designed to be a radio frequency shield. The invention provides for an inner surface of the housing to have a heat conducting element which extends from the housing to the component and produces a thermally conductive connection between the component and the housing.

### CLAIM FOR PRIORITY

This application claims priority to Application No. 01107769.0 which was filed in the English language on Apr. 4, 2001.

### TECHNICAL FILED OF THE INVENTION

The invention relates to a radio frequency module of an audio appliance, and in particular, to a radio frequency module having at least one electrical component which produces heat loss and is mounted on a printed circuit board arranged inside a metal housing designed to be a radio frequency shield.

### BACKGROUND OF THE INVENTION

Radio frequency modules, such as a tuner in a radio set, have a metal shielding housing to prevent other components from being influenced by radio frequency radiation. The radio frequency module generally includes a plurality of electrical components which produce heat loss. The housing designed to be a radio frequency shield makes dissipation of the heat loss to the environment more difficult, which means that high temperatures may arise inside the housing which result in damage or destruction of the electrical components. Radio frequency modules of the type described above are known, for example, from DE 199 26 763 A1 and DE 196 36 181 A1. These known radio frequency modules have no particular measures to optimize heat dissipation.

EP 0 489 341 A1 discloses a housing for electrical circuits which ensures improved heat dissipation of heat loss from a component inside the housing. The housing is provided, in particular, for small compact circuits which are constructed as independent units on circuit boards or printed circuit boards and are used for controlling or regulating electric drives, motors, relays or any other design components. The board holding the electrical components is located inside a metal housing which is generally not completely closed. To improve heat dissipation, the housing may be filled with a potting compound, so that there is increased conduction of heat from a power transistor producing heat, for example, to the metal housing. Such potting is an additional cost factor, however, and additionally prevents the circuit from being repaired. In addition, on the basis of EP 0 489 341 A1, provision is made for an open housing point to be covered by a heat sink made of highly thermally conductive material. This heat sink is mounted such that it is directly connected to the component producing heat. However, such an embodiment requires a high level of measurement accuracy for arranging the component on the board and the board inside the housing, since any air gap remaining between the component and the heat sink means that the desired heat dissipation is not ensured. To be able to eliminate remaining gaps, provision is again made for the housing to be potted.

### SUMMARY OF THE INVENTION

The invention discloses a radio frequency module such that dissipation of heat loss from the interior of the housing is improved.

In one embodiment of the invention, an inner surface of the housing has a heat conducting element which extends from the housing to the component and produces a thermally conductive connection between the component and the housing.

In one aspect, the shielding housing of a radio frequency module is made of a metal material. Metal materials are known to be good conductors of heat. Optimized heat dissipation from the interior of the housing can therefore be achieved by connecting the heat source, namely a component producing heat loss, to the housing by means of a highly thermally conductive connection. The high level of thermal conductivity provided by the metal shielding housing means that the heat loss supplied to the housing is distributed well over the entire housing, so that a large cooling surface is available. Owing to the aforementioned fact that metals are good conductors of heat, the heat conducting element will preferably be in the form of a metal element.

The heat conducting element is preferably permanently connected to the housing. This results, firstly, in very good heat transfer from the heat conducting element to the housing, and secondly, in reliable fixing for the heat conducting element. The heat conducting element is preferably of resilient design. This ensures that the heat conducting element is always bearing with a certain contact pressure on a surface of the component producing heat loss. In addition, the resilient design compensates for spacing tolerances between the housing and the component.

In another embodiment, the surface of the housing which has the heat conducting element faces a surface of the printed circuit board on which the component producing heat loss is arranged. This ensures that the design of the heat conducting element is simple. Complex shapes to produce a connection between the component and the housing are not necessary. In this embodiment, the heat conducting element is preferably in thermally conductive contact with a surface of the electrical component which is remote from the printed circuit board.

In still another embodiment, the housing is of at least two-part design, and the printed circuit board is mounted on a first housing part and the heat conducting element is mounted on a second housing part. The result of this is particularly simple assembly. In this context, the printed circuit board can first be mounted in the first housing part, and the second housing part, which holds the heat conducting element, is then connected to the first housing part. If the heat conducting element is arranged appropriately, this connecting operation also produces the thermally conductive connection between the heat conducting element and the component on the printed circuit board directly.

The radio frequency module is, in particular, the tuner in a car radio. Besides the pure radio function, modern car radios integrate other functions, such as that of a CD player or of a cassette player. Car radios are manufactured in standardized dimensions, so that the individual modules inside the car radio housing are very close together. In the case of such a compact design where the individual modules are not very far apart, both reliable radio frequency shielding and good heat dissipation in the tuner are of particular importance.

The component producing heat loss may be, for example, an integrated circuit, such as a tuner IC.

### BRIEF DESCRIPTION OF THE DRAWINGS

The invention is described in more detail below with the aid of illustrative embodiments. In the drawings:

FIG. 1 shows a schematic cross section of a tuner housing.

FIG. 2 shows a view of a housing part with a heat conducting element.

FIG. 3 shows an exterior view of a tuner housing.

FIG. 4 shows fundamental components of a car radio.

### DETAILED DESCRIPTION OF THE PREFERRED EMBODIMENTS

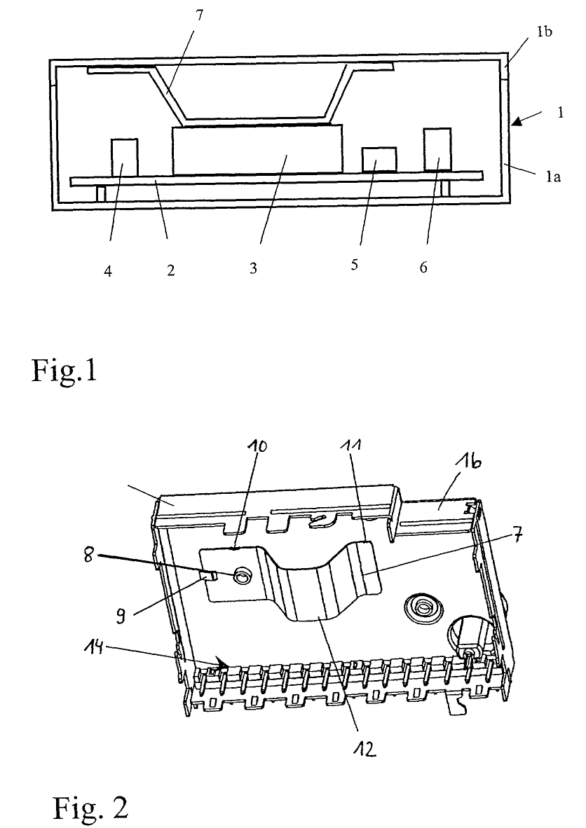

FIG. 1 shows a schematic cross section through a two-part housing 1 having a first housing part la and a second housing part 1b. Mounted in the first housing part la is a printed circuit board 2. The printed circuit board 2 includes, in addition to a component 3 producing heat loss, components 4, 5, 6, which are electrically connected via conductor tracks (not shown in more detail) to produce a circuit. Mounted on the inner surface of the second housing part 1b is a heat conducting element 7 which, when the housing 1 has been assembled, bears on the surface of the component 3 and thus produces a thermally conductive connection between the component 3 and the housing 1. To improve the heat transfer between the component 3 and the heat conducting element further, thermally conductive paste or the like can be applied to the component 3 or to the heat conducting element 7.

The heat loss produced by the component 3 is thus conducted via the heat conducting element 7 to the housing 1, which is likewise a very good conductor of heat. According to the invention, therefore, the housing 1 performs a dual function. Specifically, the housing 1 performs not only the shielding function but also the function of a heat sink. This allows the temperature inside the housing 2 to be reduced, which prevents damage to the components as a result of excessive temperature. A reduced temperature also has a positive effect on the lifetime of the components.

FIG. 2 shows an interior view of the second housing part 1b. The heat conducting element 7 is directly connected to an inner surface of the second housing part 1b. In the illustrative embodiment, the housing part 1b has a fixing element 8 and also a retaining element 9. The heat conducting element 7 is connected (preferably, permanently) to the housing part 1b at one end, so that a resilient effect is achieved together with the corrugated shape of the heat conducting element 7. The heat conducting element 7 has two contact surfaces 10, 11 with respect to the housing part 1b and also a contact surface 12 which, when the housing has been assembled, bears on the component producing heat. In addition, the second housing part 1b has an antenna connection 13 and a connector strip 14 which are each connected to the printed circuit board and ensure the supply and removal of signals to the printed circuit board.

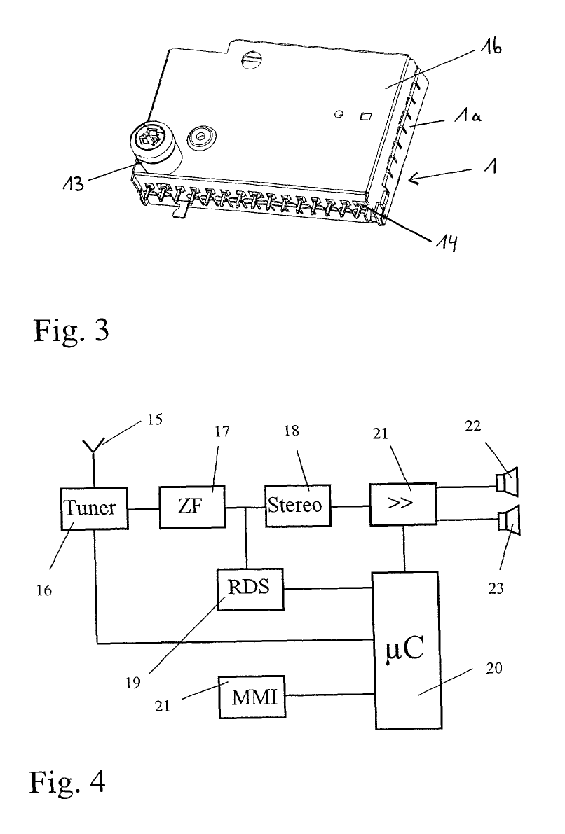

FIG. 3 shows the shielding housing when it has been assembled. The substantially, completely closed housing affords good radio frequency shielding and means that a large cooling surface is available at the same time. Such a radio frequency module may, in particular, be the tuner in a car radio. In this case, the connector strip 14 is used to produce an electrical connection to the other components in the car radio.

FIG. 4 shows a few fundamental components of a known car radio. The antenna 15 receives radio broadcast signals from a radio station. The received signals are passed on to a tuner 16. The output signal from the tuner 16 is converted to an intermediate frequency in the intermediate frequency stage 17. The output signal from the intermediate frequency stage 17 is supplied to a stereo decoder 18 and to an RDS decoder 19. The tuner 16 is driven by a control circuit 20. The control circuit 20 is supplied with signals from the RDS decoder 19. In addition, the control circuit 20 is connected to one or more input/output modules 21 (control elements, display). Output signals from the stereo decoder 18 and from the control circuit 20 are supplied to an AF amplifier 21, whose output signals are audibly reproduced via the loudspeakers 22, 23 as audio signals. The use of a radio frequency module with optimized heat dissipation, according to the invention, as tuner 16 contributes to reliable and fault-free operation of the car radio.

What is claimed is:

1. A radio frequency module of an audio appliance, comprising:
at least one electrical component which produces heat loss and is mounted on a printed circuit board arranged inside a metal housing configured as a radio frequency shield, wherein
an inner surface of the housing has a heat conducting element which extends from the housing to the component and produces a thermally conductive connection between the component and the housing.

2. The radio frequency module as claimed in claim 1, wherein the heat conducting element is permanently connected to the housing.

3. The radio frequency module as claimed in claim 1, wherein the inner surface of the housing which has the heat conducting element faces a surface of the printed circuit board on which the component producing heat loss is arranged.

4. The radio frequency module as claimed in claim 1, wherein a surface of the electrical component which is remote from the printed circuit board is in thermally conductive contact with the heat conducting element.

5. The radio frequency module as claimed claim 1, wherein the housing is at least a two-part design, and the printed circuit board is mounted on a first housing part and the heat conducting element is mounted on a second housing part.

7. The radio frequency module as claimed claim 1, wherein the radio frequency module is configured as a tuner.

8. The radio frequency module as claimed in claim 7, wherein the tuner is a tuner in a car radio.

9. The radio frequency module as claimed claim 1, wherein the electrical component is an integrated circuit.
